(19) United States
(12) Patent Application Publication
(10) Pub. No.: US 2026/0169391 A1
(43) Pub. Date: Jun. 18, 2026

(54) GRAYSCALE PHOTOLITHOGRAPHY METHOD WITH IMPROVED ACCURACY

(71) Applicant: COMMISSARIAT A L'ENERGIE ATOMIQUE ET AUX ENERGIES ALTERNATIVES, Paris (FR)

(72) Inventors: Ujwol PALANCHOKE, Grenoble Cedex 09 (FR); Florian TOMASO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/423,660

(22) Filed: Dec. 17, 2025

(30) Foreign Application Priority Data
Dec. 17, 2024 (FR) FR2414379

(51) Int. Cl. G03F 7/00; G03F 7/16

(52) U.S. Cl. CPC G03F 7/70416; G03F 7/0005; G03F 7/0035; G03F 7/168

(57) ABSTRACT

A grayscale lithography method including a provision of a substrate covered by a first photosensitive resin layer, an exposure of this layer to a first insolation radiation (R₁) through a first mask, and a development. The first mask is configured to form, in the resin, an assembly of first structures each having, a height comprised in a first range of heights (Δ1). The method includes a formation of a second photosensitive resin layer, an exposure of this layer to a second insolation radiation (R₂) through a second mask, and a development. The masks are configured to enable the formation of an assembly of second structures, each having a height comprised in a second range of heights (Δ2) disjoint from the first range of heights (Δ1).

### TECHNICAL FIELD

The present invention relates to the field of photolithography, more specifically, that of grayscale lithography. It relates, in particular, to manufacturing structures comprising elements of different heights.

### PRIOR ART

Grayscale lithography is a photolithography technique enabling the production of three-dimensional (3D) microstructures in one single lithography and development step. It is particularly used in manufacturing optical microelements, MEMS (microelectromechanical systems), MOEMS (microoptoelectromechanical systems), microfluid devices or also textured surfaces.

This technique is based on the fact of making the thickness vary along a dimension Z on which a photosensitive resin is insolated by modulating, in the space, the ultraviolet (UV) dose received by the resin. Once the insolated portions are developed, the resin has a 3D structuration (scanning electron microscope (SEM) views represented in FIGS. 1B and 1D), and can for example, serve as a mould for manufacturing 3D microstructures.

The ultraviolet dose received locally by the resin can, in particular, be modulating by playing on the dimensions and the positioning of opaque zones present on the lithography mask (FIGS. 1A and 1C). These opaque zones are typically produced by chrome deposition on a glass or quartz mask.

Grayscale lithography thus makes it possible to obtain 3D microstructures having a characteristic height going from one hundred nanometres to a few hundreds of micrometres. However, the accuracy of the height at each point of the microstructure is very dependent on the manufacturing variability of the mask and of the variability of the method. The variability of the final height of the microstructure is higher than the pattern density than the mask is low, as FIGS. 2A and 2B illustrate. These figures are experimental results obtained for a resin layer of an initial thickness of 1.6 μm, in which different pillars have been formed. In FIG. 2A, it clearly appears that the error bars, proportional to three times the standard deviation (3a), are greater than for higher densities. FIG. 2B, which identifies the value of 36 for different density values, also shows this trend. An explanation to this phenomenon is that the regions of the resin exposed through zones of the low-density pattern mask receive an insolation dose, greater than the other regions. These regions consequently interact for longer with the development agent, which can explain a high inaccuracy on the height of the final structures formed in these regions.

The variability of the height of the structures formed is very unfavourable and limits the applications of grayscale photolithography being able to be considered. For example, certain optoelectronic devices can today be difficult to be, even cannot be manufactured by a grayscale photolithography method. The applications requiring a spectral signature at different wavelengths, for example, like Fabry-Perot sensors, require a very accurate control of the height of the cavities associated with each wavelength. If the sizing of the different channels associated with as many wavelengths within a Fabry-Perot cavity (see FIG. 2C) is considered: for a sought spectral range R and a given number N of channels, the difference Δλ between the wavelengths from one channel to another is Δλ=R/N and the difference ΔH between the channel heights from one channel to another is ΔH=Aλ/2n, with n the reflection index of the material of the cavity. If a spectral range going from 400 nm to 1000 nm (Δλ=700 nm), for example, is sought, with N=32 and n=1.5, this leads to ΔH=7.3 nm. The height of the smallest cavity (for λ=400 nm) would be around 133 nm and that of the largest cavity (for λ=1100 nm), of 366 nm. It appears that such an accuracy on as varied cavity heights, in particular from an initial resin current thickness of around 1.5 μm, is reachable with current grayscale photolithography methods.

There is therefore a need for a solution making it possible to produce structures of different sizes with a good accuracy by grayscale photolithography.

### SUMMARY

To achieve this aim, according to a first aspect, the invention relates to a grayscale lithography method, comprising:
a. a provision of a substrate having an upper face extending mainly into a horizontal plane, the substrate being covered by a first photosensitive resin layer,
b. an exposure of the first photosensitive resin layer to a first insolation radiation through a first mask, then a development of the first photosensitive resin layer, the first mask being configured such that once the first resin layer is developed, this has an assembly of first structures, each having a height comprised in a first range of heights, the height of the first structures being measured along a so-called vertical direction, perpendicular to the horizontal plane,
c. a formation on the upper face of the substrate of a second photosensitive resin layer,
d. an exposure of the second photosensitive resin layer to a second insolation radiation through a second mask and a development of the second photosensitive insolation radiation through a second mask and a development of the second photosensitive resin layer, the first mask and the second mask being configured, such that the development of the second resin layer enables the formation of an assembly of second structures, each having a height comprised in a second range of heights disjoint from the first range of heights, the height of the second structures being measured along the vertical direction, the first structures and the second structure being located in distinct zones, projecting into the horizontal plane. The first mask and the second mask are moreover configured, such that within the assembly of first structures, at least two first structures have distinct heights, and such that within the assembly of second structures, at least two second structures have distinct heights.

By proceeding as the invention proposes, it is possible, when it is sought to form an assembly of structures having varied heights, as is the case in a lot of optoelectronic devices, to first form, using the first mask, a first assembly of structures having the smallest heights. Structures having greater heights can then be formed, using the second resin layer and the second mask. It is understood that it is not compulsory to form the smallest to the largest structures, the groups of structures of different sizes can be formed in any order.

By thus proceeding sequentially, using two photolithography steps, it is avoided to have to simultaneously form structures having heights which are very different from one another. In the case of one single resin layer dedicated to the formation of all the structures, it is necessary to proceed with a material removal over a very large depth to form the smallest structures. The method according to the invention makes it possible to avoid this, since the smallest structures can be formed from a resin layer, the height of which must not necessarily enable the manufacture of larger structures.

Thus, the method according to the invention makes it possible to release the stresses on the lithography mask, as well as on the conditions of the method. Consequently, the errors in line with these two parameters are limited. The actual heights of the structures obtained by the method according to the invention move a lot closer to the target values with respect to the methods of the prior art.

Furthermore, it is possible, according to an embodiment of the invention, to preserve a residual layer of the first resin layer, which will form part of the second structures formed during the second lithography step. By using the thickness of the residual layer to form the second structures, the required thickness of the second resin layer is limited. This makes it possible to carry out a lithography step in a thinner resin layer, which is beneficial to the accuracy on the height of the structures.

The method according to the invention thus makes it possible to simultaneously limit the impact of the variability on the mask and of the variability of the method. This is conveyed by a clear improvement of the manufacturing accuracy with respect to current photolithography methods.

A second aim of the present invention relates to a use of the method according to the first aspect of the invention in the manufacture of a photonic device taken from among: a multispectral filter, a phase array, an imager, a coupler.

The advantages provided by the method according to the first aspect of the invention apply mutatis mutandis to this use.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1D represent grayscale lithography masks and scanning electron microscope views insolated through these masks, then developed. FIGS. 1A and 1B relate to the manufacture of 3D structures having plates at different heights. FIGS. 1C and 1D relates to the manufacture of 3D microlenses having a dome shape.

FIG. 2A is a graph illustrating the height of pillars obtained by grayscale photolithography from different pattern densities on the mask, as well as the error on this height.

FIG. 2B illustrates the error on the height of pillars obtained by grayscale photolithography from different pattern densities on the mask.

FIG. 2C illustrates the sizing of the different channels associated with as many wavelengths within a Fabry-Perot cavity.

FIGS. 3A to 3E illustrate a first embodiment of the method according to the invention, in which the second structures are fully formed in the second resin layer.

FIGS. 4A to 4E illustrate a second embodiment of the method according to the invention, in which the second structures are formed by a residual layer of the first resin layer and by the second resin layer.

FIGS. 5A to 5F illustrate a third embodiment of the method according to the invention, in which the second insolation step is carried out through the first mask having undergone a translation relating to the substrate with respect to the first insolation step.

FIGS. 6A to 6D illustrate the option of using the present invention to manufacture a photonic coupler.

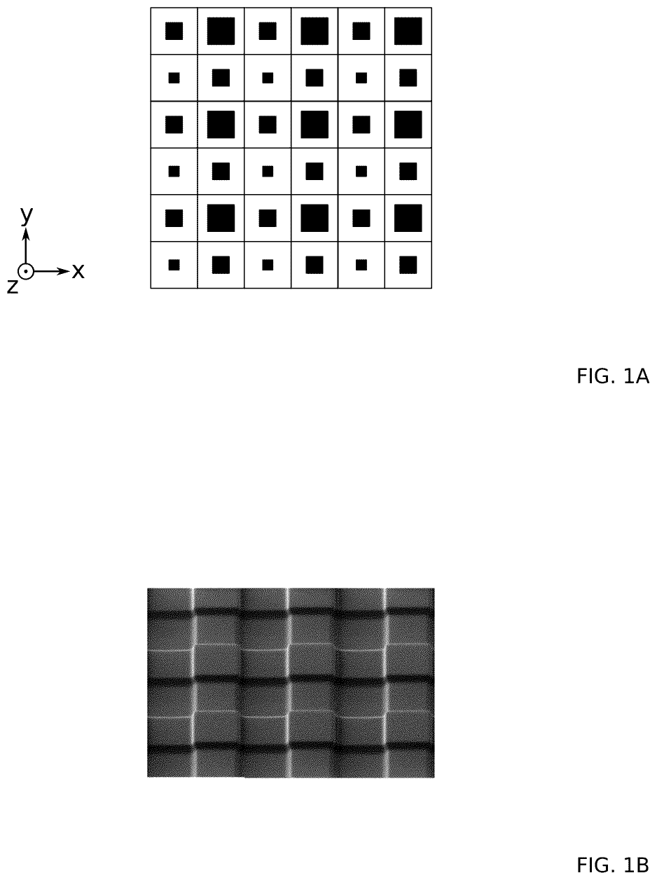

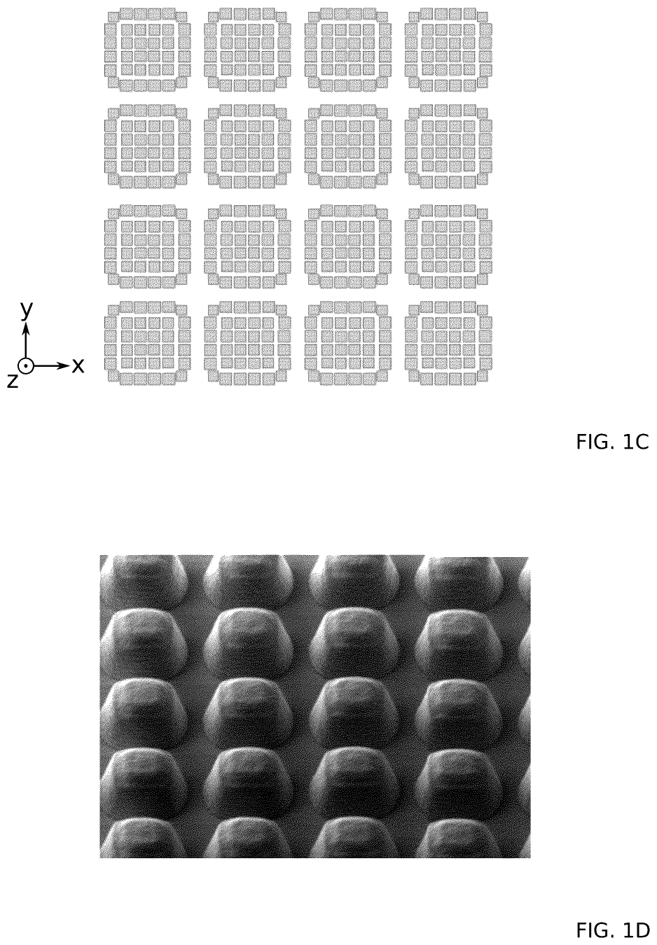

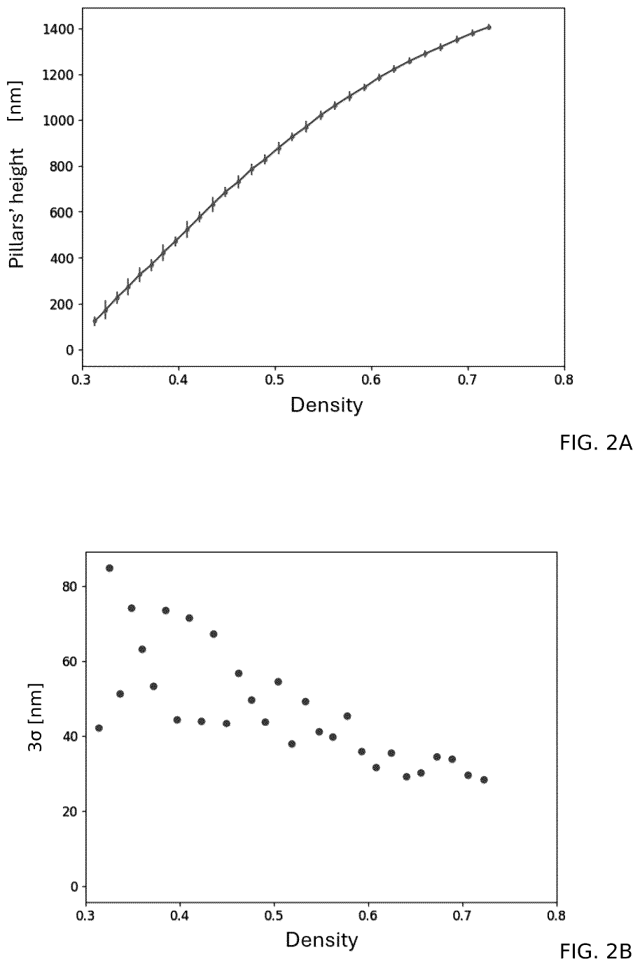

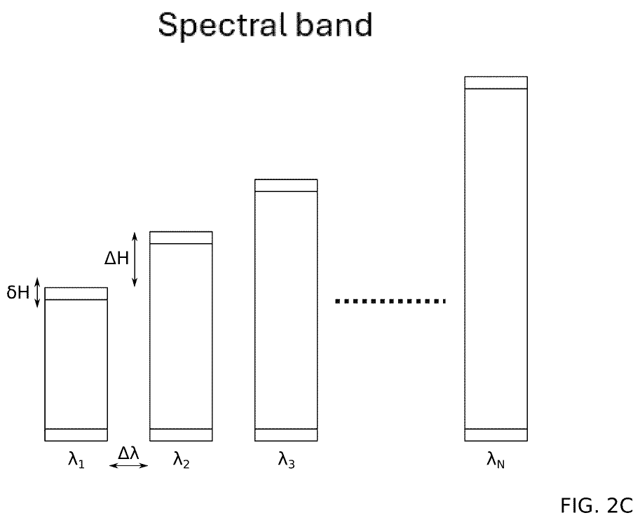

The drawings are given as examples and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to a preferred example, the first mask and the second mask are configured, such that the first range of heights and the second range of heights each extend over a range, less than or equal to 300 nm, preferably less than or equal to 200 nm, preferably less than or equal to 100 nm. Thus, each lithography step is dedicated to the production of structures, the different heights of which are in a restricted range. This makes it possible to improve the accuracy on the height of the structures.

According to a preferred example, the first mask and the second mask are configured, such that the heights of the first structures are less than the heights of the second structures.

According to a preferred embodiment, the method further comprises, after the exposure and the development of the first photosensitive resin layer and before the formation of the second photosensitive resin layer, a hardening of the first photosensitive resin layer.

According to an embodiment, the first mask has zones which are transparent to the first insolation radiation, such that the development of the first resin layer causes, outside of the first structures, its removal over its entire height along the vertical direction.

According to an embodiment, the first mask is configured, such that once the first resin layer is developed, this has, outside of the first structures, a residual layer, and each of the second structures, comprises a part of the residual layer. By preserving a residual layer, the surface topography created by the first developed resin layer is minimised. The deposition of the second resin layer is therefore done on a surface having a lower surface topography. The roughness transferred to the upper surface of the second resin layer is limited. This embodiment thus makes it possible to minimise the surface roughness of the second structures.

According to an example, the first mask has zones which are opaque to the first insolation radiation, such that the residual layer has, at least locally, a height equal to a height of the first resin layer, before insolation and development, the height of the residual layer and the height of the first resin layer being measured along the vertical direction.

According to an example, the second mask is the first mask having undergone a translation relative to the substrate.

According to an embodiment, the second photosensitive layer is deposited on the first structures, and the second mask has zones which are transparent to the second insolation radiation, such that the development of the second resin layer causes the updating of the first structures.

According to an example, the at least two first structures having distinct heights have a height difference, called first height difference, greater than or equal to 20 nm.

According to an example, the at least two second structures having distinct heights have a height difference, called second height difference, greater than or equal to 20 nm.

In the scope of the present invention, an organic or organo-mineral being able to be shaped by an exposure to an electron, photon, X-ray beam, a light beam in the ultraviolet range, in the extreme ultraviolet (EUV) range or in the deep ultraviolet (Deep UV) range, typically in the wavelength of 193 nm to 248 nm, emission lines of a mercury lamp, that is: 365 nm for the I line, 435 nm for the G line and 404 nm for the H line are qualified as a resin.

The invention also applies both to positive resins, i.e. the exposed part of which becomes soluble to the revealer and where the non-exposed part remains insoluble, and to negative resins, i.e. the non-exposed part of which becomes soluble to the revealer and where the exposed part remains insoluble.

The contrast of a resin, commonly referenced γ, conveys the effectiveness of the performance named in literature as “threshold performance” of the resin. The greater the contrast is, the more necessary a low dose variation is, such that the resin passes from a state in which it cannot be developed to a state in which it can be developed (or conversely, for a negative resin). The value of the contrast γ of a resin, whatever the positive or negative tonality, is generally determined by the gradient of the curve according to the following equation:

$$\frac{e}{{e}_{0}} = γ ln ( \frac{{D}_{0}}{D} ) ,$$

where e is the thickness of the rein film after exposure and development, e₀ is the thickness of the initial resin film, D is the exposure dose applied and Do is the dose at which the entire thickness of the film is developed.

By “nature” of a material such as a resin, this means its chemical composition, i.e. the nature and the proportion of the species constituting the material. Two layers are considered as made of one same resin, if they have the same chemical composition.

In the present description, a quantity of energy received by a resin per surface unit is qualified as a dose. This energy can be in the form of photons (photolithography) for a photosensitive resin. It is thus the product of the intensity of the incident light radiation (generally expressed in Watt/m²) and of the exposure duration (expressed in seconds). The dose is thus usually expressed in Joules per m², or more often, in millijoules (mJ) per cm⁻² (10⁻⁴ m²) or also in mJ/m². This energy can also be in the form of electrons (electronic lithography) for an electrosensitive resin. The dose is thus usually expressed in Coulombs per m², or more often, in microcoulombs (μC) per cm⁻² (10⁻²m²) that is in ρC/m².

The pattern density D to be imposed at the mask to obtain a given structure height can be obtained by the following equations:

$${h}_{r e s i n} = ( {h}_{0} - {h}_{d a r k} ) - [ {e}^{{e}_{1} + {e}_{2} * m + {e}_{3} * {m}^{2}} + {e}_{4} * dose ]$$

$$m = {e}^{- C * d o s e}$$

$$dose = {{D}_{s r c} ( 1 - D )}^{2}$$

With: hᵣₑₛᵢₙ the desired structure height, h_{dark} the erosion height of the resin without exposure, “dose”, the exposure dose and h₀, the initial resin thickness after deposition and before exposure/development. e₁, e₂, e₃ and e₄ are parameters being able to be obtained by extraction from the contrast curve. C is the Dill coefficient of the resin, generally provided by the resin manufacturer.

By a parameter “substantially equal to/greater than/less than” a given value, this means that this parameter is equal to/greater than/less than the given value, plus or minus 20%, even 10%, even 5% of this value. By a parameter “substantially between” two given values, this means that this parameter is, as a minimum, equal to the smallest given value, plus or minus 20%, even 10%, of this value, and as a maximum, equal to the greatest given value, plus or minus 20%, even 10%, of this value.

In the present patent application, thickness will preferably be referred to for a layer, and height will preferably be referred to for a structure or a device. The thickness is taken along a direction normal to the main extension plane of the layer, and the height is taken perpendicularly to the horizontal plane XY Thus, a layer typically has a thickness along the direction called vertical Z, when it extends mainly along the horizontal plane XY The relative terms “on”, “under”, “underlying” preferably refer to positions taken along the vertical direction Z.

The method according to the invention will now be described in more detail, in reference to the figures.

A first step of the method comprises the provision of a substrate 10. This substrate has an upper face 11, extending mainly along the horizontal plane XY The substrate 10 can, for example, be taken from among a glass substrate, a silicon substrate or also a substrate with CMOS (complementary metal oxide semiconductor) components.

The substrate 10 is covered by a first photosensitive resin layer 20. Advantageously, the first resin layer 20 is in contact with the upper face 11 of the substrate 10. The first resin layer 20 has a thickness e₂₀ measured along the vertical direction Z, perpendicular to the horizontal plane XY e₂₀ is typically less than or equal to 1 μm, for example, of between 200 nm and 1 μm, for example, around equal to 500 nm.

A second step of the method comprises the insolation of the first resin layer 20 through a first mask 100. This insolation step is carried out by exposure of the first resin layer 20 to a first incident radiation R₁ through the first mask 100. Then, the development of the first photosensitive resin layer 20 is proceeded with. The features of the first mask 100 will be described further, according to the embodiments.

This second step enables the formation of first structures 25 in the first resin layer 20. These first structures 25 each have a height h₂₅₁, h₂₅₂, h₂₅₃, h₂₅₄ measured along the vertical direction Z. When the first resin layer 20 is in contact with the substrate 10, the height of the first structures 25 is measured from the upper face 11 of the substrate 10.

The height of each first structure 25 is in a first range of heights referenced Δ₁. Thus, the first mask 100 is dedicated to the manufacture of structures, the height of which is in this first range Δ₁.

The height of each first structure 25 is typically greater than or equal to 50 nm.

Within the assembly of first structures 25, at least two first structures 25 have different heights. The height difference between these at least two first structures 25 (being able to be called “first height difference”) is typically greater than or equal to 20 nm and/or less than or equal to 50 nm. The first height difference is, for example, substantially equal to 20 nm. According to a particular example, the first structures 25 all have different heights (in other words, for four first structures 25, h₂₅₁, h₂₅₂, h₂₅₃ and h₂₅₄ all have different values).

Advantageously, once the first structures 25 are formed, a hardening of the first resin layer 20 is proceeded with. This comprises, in particular, a hardening of the first structures 25.

A third step of the method comprises the formation of a second photosensitive resin layer 30 on the substrate 10, more specifically, on the upper face 11 of the substrate 10. Typically, the second resin layer 30 covers the portions of the first resin layer 20 remaining after its development. The second resin layer 30 has a thickness e₃₀ measured along the vertical direction Z, perpendicular to the horizontal plane XY. e₃₀ corresponds to the maximum height taken by the second resin layer. e₃₀ is chosen according to the height of the highest second structure 35 that is sought to be manufactured.

The second photosensitive resin layer 30 can be of the same nature as the first photosensitive resin layer 20. It is also possible to use resins of different natures.

A fourth step of the method comprises the insolation of the second resin layer 30 through a second mask 200. This insolation step is carried out by exposure of the second resin layer 30 to a second incident radiation R₂ through the second mask 200. Then, the development of the second photosensitive resin layer 30 is proceeded with. The features of the second mask 200 will be described further, according to the embodiments. Preferably, the second mask 200 is not the assembly of first structures 25.

This fourth step enables the formation of second structures 35. The second structures 35 can each be fully formed by the second resin layer 30, or partially by the second resin layer 30 and partially by the first resin layer 20. These two options will be detailed further.

The second structures 35 each have a height h₃₅₁, h₃₅₂, h₃₅₃ measured along the vertical direction Z.

The height of each second structure 35 is comprised in a second range of heights referenced Δ₂. Thus, the second mask 200 (optionally combined with the first mask 100) is dedicated to the manufacture of structures, the height of which is in this second range Δ₂. The first range of heights Δ₁ and the second range of heights Δ₂ are disjoint. In other words, their intersection is zero.

The height of each second structure 35 is typically greater than or equal to 500 nm.

Within the assembly of second structures 35, at least two second structures 35 have different heights. The height difference between these at least two second structures 35 (being able to be called “second height difference”) is typically greater than or equal to 20 nm and/or less than or equal to 50 nm. The second height difference is, for example, substantially equal to 20 nm. According to a particular example, the second structures 35 all have different heights (in other words, for three second structures 35, h₃₅₁, h₃₅₂ and h₃₅₃ all have different values).

Advantageously, once the second structures 35 are formed, a hardening of the second resin layer 30 is proceeded with. This comprises, in particular, a hardening of the second structures 35.

The first radiation R₁ and the second radiation R₂ to which the resin layers 20, 30 are subjected, each have a main direction substantially perpendicular to the horizontal plane XY These radiations R₁, R₂ are typically UV (ultraviolet) radiations, these can thus be radiations emitting in a wavelength range going from around 100 nm to around 400 nm, for example, 365 nm. This can however also be radiations having wavelengths outside of this range. Generally, radiations emitting in a wavelength going from around 90 nm to around 500 nm can be considered in a non-limiting manner. The first radiation R₁ and the second radiation R₂ can be similar or different.

Ideally, the resin(s) used has/have at least one of the following features:
a. A substantially linear response between the radiation dose to which it is exposed and the thickness on which it is insolated.
b. A sufficiently low contrast, for example, less than 2, to enable the implementation of grayscale lithography, but sufficiently high, for example, greater than 1, to avoid too high exposure times. Advantageously, the contrast is between 1.1 and 1.5.
c. Good film-forming properties, guaranteed, for example, by the presence of a film-forming agent in its composition.
d. A low inhibition of the dissolution.

Resins, produced by the company Micro Resist Technology having the commercial references ma-P 1215G, ma-P 1225G and ma-P 1275G can, in particular, be mentioned as examples of resins which can be used in the scope of the invention.

The hardening of the resins can be done thermally or chemically.

The first mask 100 and the second mask 200 have transparent zones and opaque zones.

The transparent zones correspond to regions of the mask 100, 200, the composition of which is transparent to the insolation radiation R₁, R₂, while the opaque zones correspond to regions of the mask 100, 200, the composition of which is opaque to the insolation radiation R₁, R₂. A zone is, for example, considered as opaque, when it stops at least 90% of the incident radiation R₁, R₂. A zone is considered as transparent, when it transmits at least 60% of the incident radiation R₁, R₂.

For example, the mask can be a glass mask with chrome depositions. The opaque zones thus correspond to the zones of the mask 100, 200 where chrome has been deposited, while the transparent zones correspond to the zones remaining chrome-free.

According to the principle of grayscale lithography, for a given region of the mask 100, 200, the surface density D of the opaque zones within this region determines the radiation dose received by the region of the underlying resin layer 20, 30 and therefore, consequently, the thickness e on which this region of the resin layer 20, 30 is insolated by the radiation R₁, R₂. This density D is typically modulated from one region to another of the mask 100, 200 so as to spatially modulate the insolated thickness in the resin layer 20, 30.

For a given region of the mask, the surface density D of the opaque zones is the ratio between the surface of the region occupied by the opaque zones and the total surface of the region. These surfaces can, for example, be evaluated at a lower face of the mask 100, 200 facing the resin layer 20, 30 during the insolation. It is typically on this face that the depositions of material (for example, chrome) are done, forming the opaque zones.

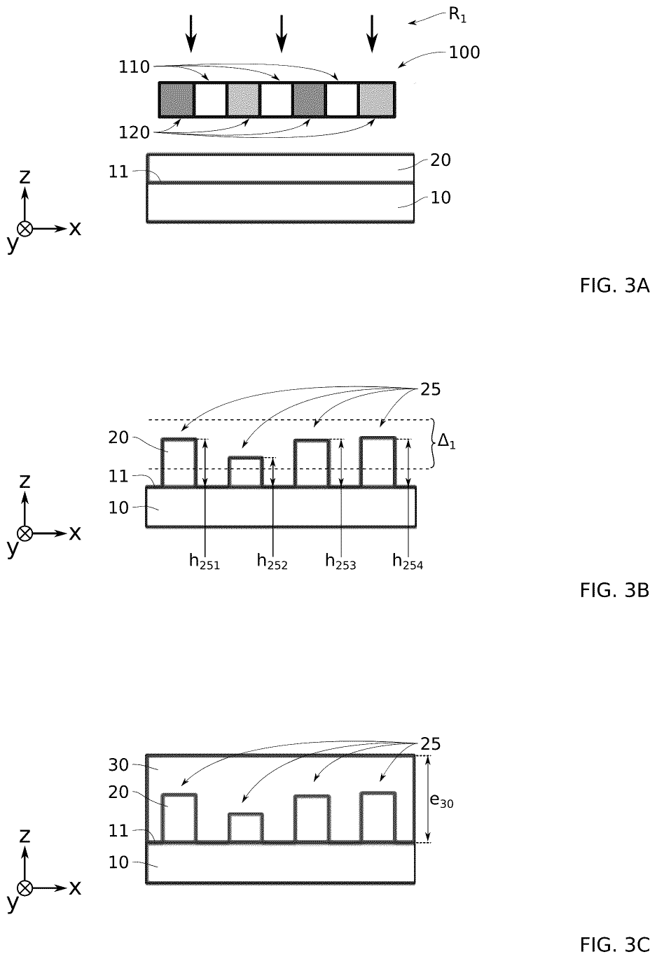

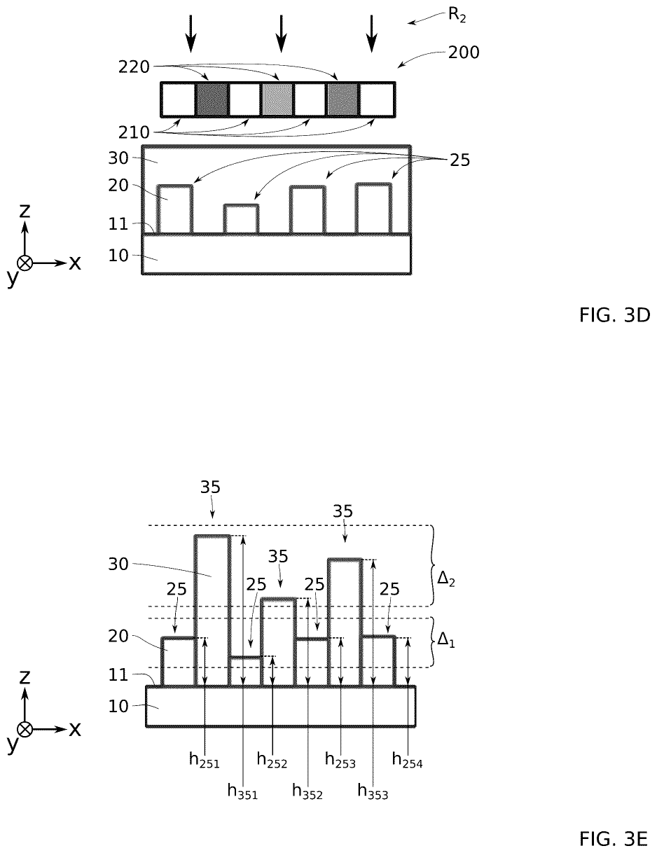

A first embodiment of the method according to the invention will now be described in reference to FIGS. 3A to 3E.

FIG. 3A illustrates the provision of the substrate 10 surmounted by the first resin layer 20, as well as the insolation of the first resin layer 20 by the first radiation R₁ through the first mask 100.

The passage from FIG. 3A to FIG. 3B illustrates the development of the first resin layer 20. Thus, a plurality of first structures 25 formed in the first resin layer 20 is obtained.

As illustrated, the height h₂₅₁, h₂₅₂, h₂₅₃, h₂₅₄ of each first structure 25 is in the first range Δ₁. As illustrated, the heights h₂₅₁, h₂₅₂, h₂₅₃, h₂₅₄ of the first structures 25 are not all identical. As indicated above, at least two are different from one another. In the example illustrated, the first structures 25 all have different heights.

Advantageously, the first mask 100 used in this embodiment comprises transparent zones 110. These transparent zones 110 make it possible to locally remove the first resin layer 20 over its entire height. The upper face 11 of the substrate 10 is thus preferably locally exposed between the first structures 25 (see FIG. 3B).

The first mask 100 moreover comprises zones 120, neither fully transparent, nor fully opaque, called intermediate zones 120, dedicated to the formation of the first structures 25 with distinct heights, according to the principle of grayscale lithography.

Advantageously, at this stage of the method, a hardening of the first resin layer 20, i.e. in this case, a hardening of the first structures 25 is proceeded with.

FIG. 3C illustrates the deposition of the second photosensitive resin layer 30 on the substrate 10. As illustrated, the second resin layer 30 extends over the first structures 25 and directly in contact with the upper face 11 of the substrate 10 in the zones where this has been updated by insolation and development of the first resin layer 20.

The second resin layer 30 thus forms an encapsulation of the first structures 25.

FIG. 3D illustrated the insolation of the second resin layer 30 by the second radiation R₂ through the second mask 200.

The passage from FIG. 3D to FIG. 3E illustrates the development of the second resin layer 30. Thus, a plurality of second structures 35 formed in the second resin layer 30 is obtained.

As illustrated, the height h₃₅₁, h₃₅₂, h₃₅₃, h₃₅₄ of each second structure 35 is in the second range Δ₂. In the example illustrated, the second range Δ₂ comprises values greater than the first range Δ₁.

As illustrated, the heights h₃₅₁, h₃₅₂, h₃₅₃ of the second structures 35 are not all identical. As indicated above, at least two are different from one another. In the example illustrated, the second structures 35 all have different heights.

Advantageously, the second mask 200 used in this embodiment comprises transparent zones 210. These transparent zones 210 make it possible to locally remove the second resin layer 30 over its entire height. Advantageously, during the insolation of the second resin layer 30, these transparent zones 210 are located in vertical alignment with the first structures 25. This makes it possible to update the first structures 25 (see FIG. 3E). With the first structures 25 preferably having undergone a hardening beforehand, they are not altered by the insolation and development step undergone by the second overlying resin layer 30.

The second mask 200 moreover comprises zones 220, neither fully transparent, nor fully opaque, called intermediate zones 220, dedicated to the formation of the second structures 35 with distinct heights, according to the principle of grayscale lithography.

Preferably, in this embodiment, when each from among the first mask 100 and the second mask 200 are considered in the same insolation position of the resin layers 20, 30, the transparent zones 110 of the first mask 100 are located in the same location as the intermediate zones 220 of the second mask 200. Moreover, preferably, the transparent zones 210 of the second mask 200 are located in the same location as the intermediate zones 120 of the first mask 100.

In other words, by superimposing the first mask 100 and the second mask 200, the following are thus preferably had, projecting in the horizontal plane XY:
a. a superimposition of the transparent zones 110 of the first mask 100 and of the intermediate zones 220 of the second mask 200, and/or
b. a superimposition of the transparent zones 210 of the second mask 200 and of the intermediate zones 120 of the first mask 100.

It is understood that the intermediate zones 120, 220 of each mask 100, 200 can, for some, correspond to opaque zones, if it is sought that the structure formed after development 25, 35 has a height equal to the deposited resin layer 20, 30.

Thus, in this embodiment, each mask 100, 200 is fully dedicated to the formation of structures 25, 35 in a range of heights Δ₁, Δ₂.

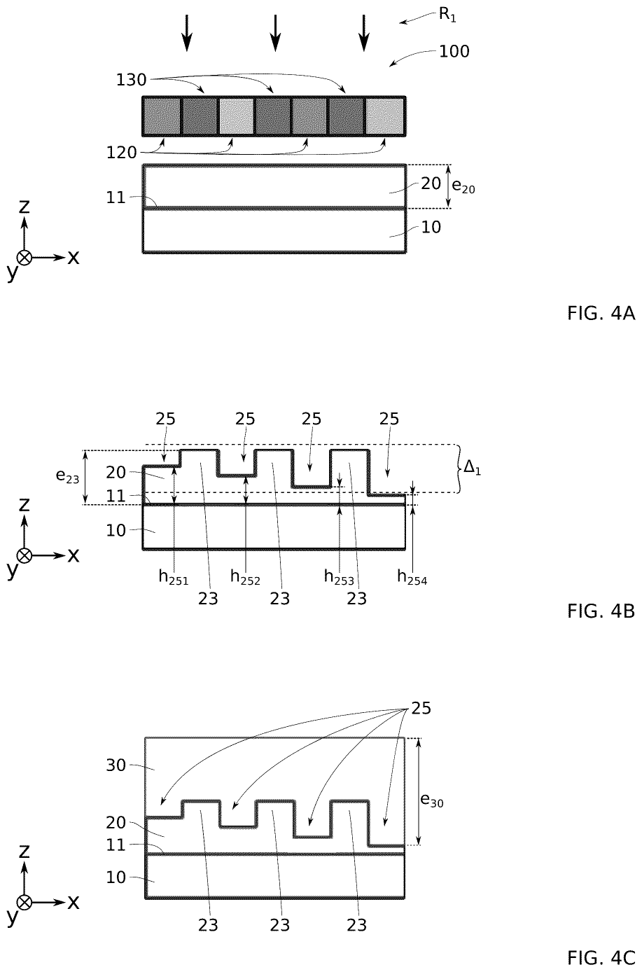

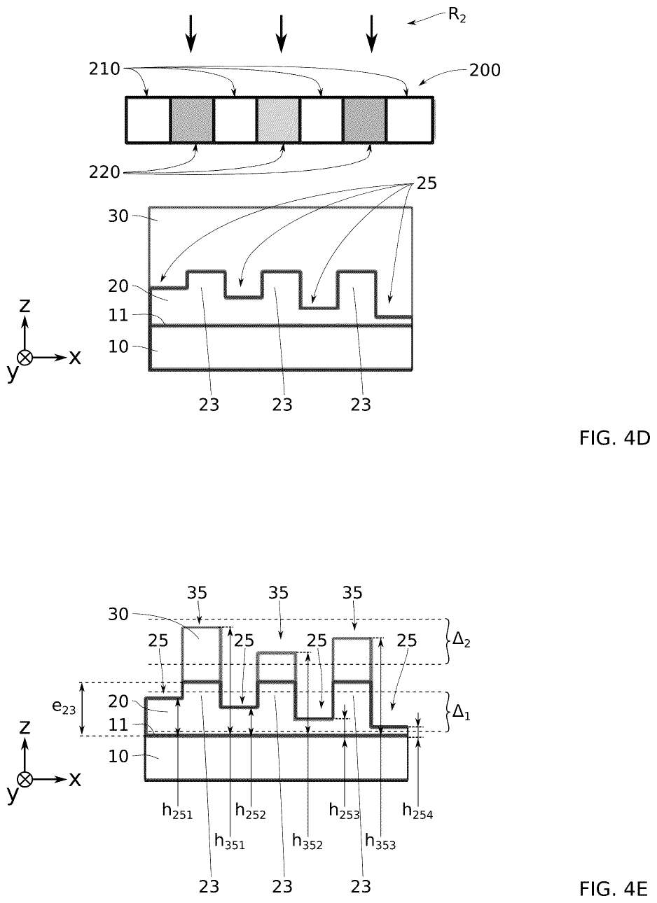

A second embodiment of the method according to the invention will now be described in reference to FIGS. 4A to 4E.

FIG. 4A illustrates the provision of the substrate 10 surmounted by the first resin layer 20, as well as the insolation of the first resin layer 20 by the first radiation R₁ through the first mask 100.

The passage of FIG. 4A to FIG. 4B illustrates the development of the first resin layer 20. As in the first embodiment, a plurality of first structures 25 formed in the first resin layer 20 is thus obtained. There again, the height h₂₅₁, h₂₅₂, h₂₅₃, h₂₅₄ of each first structure 25 is in the first range Δ₁. As illustrated, the heights h₂₅₁, h₂₅₂, h₂₅₃, h₂₅₄ of the first structures 25 are not all identical. As indicated above, at least two are different from one another. In the example illustrated, the first structures 25 all have different heights.

Advantageously, the first mask 100 used in this embodiment comprises opaque zones 130. These opaque zones 130 make it possible to locally preserve the entire height of the first resin layer 20. After development of the first resin layer 20, a residual layer 23 is thus obtained, having a thickness e₂₅₃ equal to e₂₀.

According to another example, instead of totally opaque zones 130, it is possible to use zones neither fully opaque, nor fully transparent. These zones are thus configured, such that the insolation and the development of the first resin layer 20 removes the resin on a part of its height only. After development of the first resin layer 20, a residual layer 23 is thus obtained, having a thickness e₂₅₃ of between 0 (excluded, or thus the zero thickness is taken locally) and e₂₀.

In both cases, a residual layer 23 is formed, which will serve to the formation of the second structures 35 (see further).

It is understood that the residual layer 23 does not necessarily have a uniform thickness. It is in particular possible to not locally leave any residual layer 23. It is possible to form the residual layer 23 using zones in the first mask 100 having different opaque zone densities. Forming a residual layer 23 having a non-uniform height can make it possible to reach more varied heights of second structures 35.

Like in the first embodiment, the first mask 100 moreover comprises zones 120, neither fully transparent, nor fully opaque, called intermediate zones 120, dedicated to the formation of the first structures 25 with distinct heights, according to the principle of grayscale lithography.

Advantageously, at this stage of the method, a hardening of the first resin layer 20, i.e. in this case, a hardening of the first structures 25 and of the residual layer 23 is proceeded with.

FIG. 4C illustrates the deposition of the second photosensitive resin layer 30 on the substrate 10. As illustrated, the second resin layer 30 extends over the first structures 25 and on the residual layer 23.

FIG. 4D illustrates the insolation of the second resin layer 30 by the second radiation R₂ through the second mask 200.

The passage from FIG. 4D to FIG. 4E illustrates the development of the second resin layer 30. Thus, a plurality of second structures 35 are obtained, each formed by a portion of the second resin layer 30 and a portion of the residual layer 23. The height h₃₅₁, h₃₅₂, h₃₅₃, h₃₅₄ of each second structure 35 is greater than or equal to the local thickness e₂₅₃ of the residual layer 23.

As illustrated, the height h₃₅₁, h₃₅₂, h₃₅₃, h₃₅₄ of each second structure 35 is in the second range Δ₂. In the example illustrated, the second range Δ₂ comprises values greater than the first range Δ₁.

As illustrated, the heights h₃₅₁, h₃₅₂, h₃₅₃ of the second structures 35 are not all identical. As indicated above, at least two are different from one another. In the example illustrated, the second structures 35 all have different heights.

Advantageously, the second mask 200 used in this embodiment comprises transparent zones 210. These transparent zones 210 make it possible to locally remove the second resin layer 30 over its entire height. Advantageously, during the insolation of the second resin layer 30, these transparent zones 210 are located in vertical alignment with the first structures 25. This makes it possible to update the first structures 25 (see FIG. 4E). The first structures 25 preferably having undergone a hardening beforehand, they are not altered by the insolation and development step undergone by the second overlying resin layer 30.

The second mask 200 moreover comprises zones 220, neither fully transparent, nor fully opaque, called intermediate zones 220, dedicated to the formation of the second structures 35 with distinct heights, according to the principle of grayscale lithography.

Preferably, in this embodiment, when each from among the first mask 100 and the second mask 200 are considered in the same insolation position of the resin layers 20, 30, the opaque zones 130 of the first mask 100 are located in the same location as the intermediate zones 220 of the second mask 200. Moreover, preferably, the transparent zones 210 of the second mask 200 are located in the same location as the intermediate zones 120 of the first mask 100.

In other words, by superimposing the first mask 100 and the second mask 200, the following are thus preferably had, projecting in the horizontal plane XY:
a. a superimposition of the transparent zones 110 of the first mask 100 and of the intermediate zones 220 of the second mask 200, and/or
b. a superimposition of the transparent zones 210 of the second mask 200 and of the intermediate zones 120 of the first mask 100.

It is understood that the intermediate zones 120, 220 of each mask 100, 200 can for some, correspond to opaque zones, if it is sought that the structure formed after development 25, 35 has a height equal to the deposited resin layer 20, 30.

Thus, in this embodiment, the first mask 100 is dedicated not only to the formation of the first structures 25 in the first range of heights Δ₁, but also contributes to the formation of the second structures 35 in the second range of heights Δ₂.

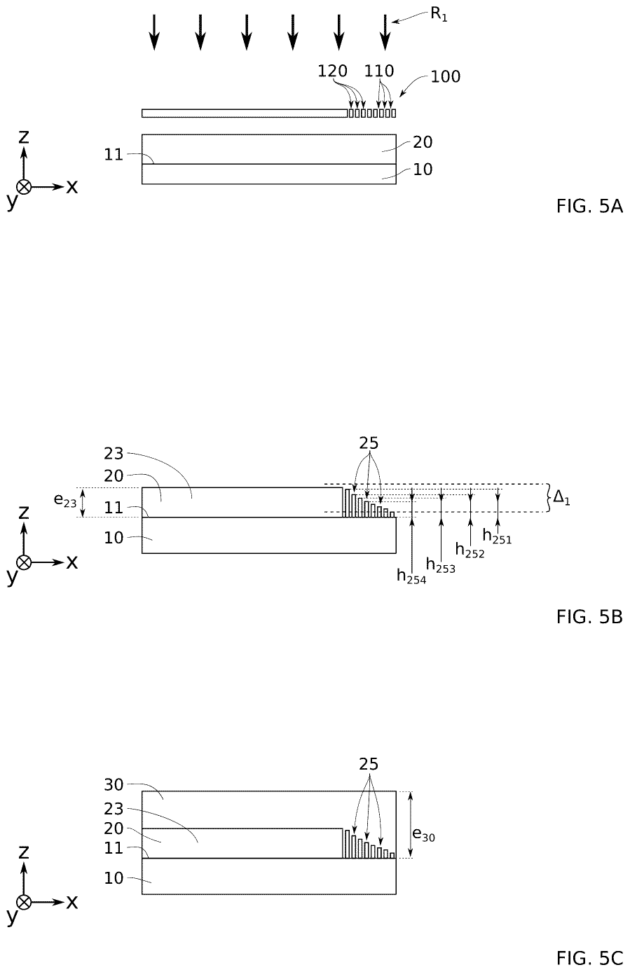

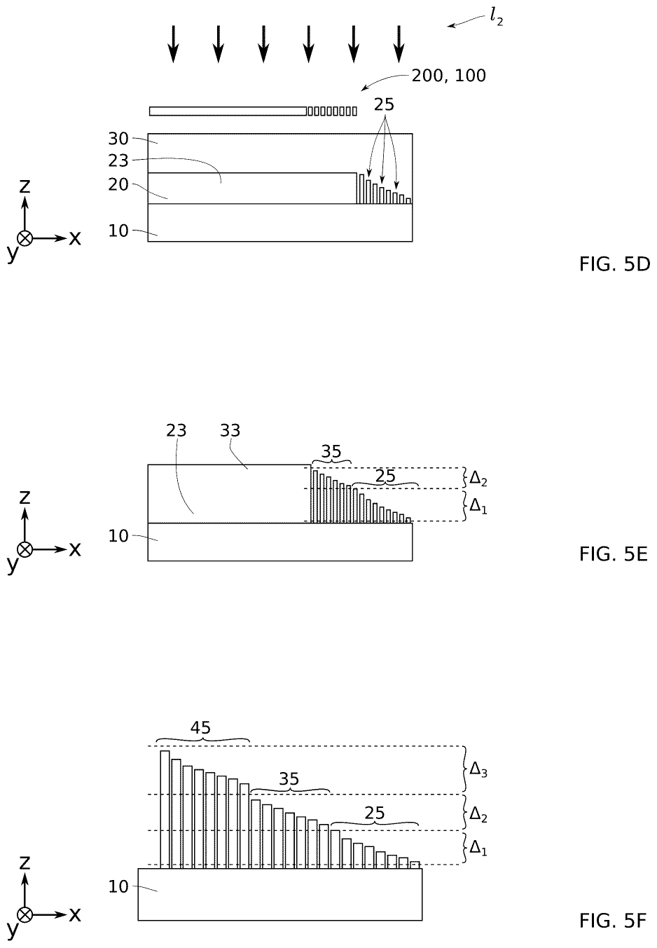

A third embodiment of the method according to the invention will now be described in reference to FIGS. 5A to 5F.

This embodiment combines the principles of the two first embodiments.

FIG. 5A illustrates the provision of the substrate 10 surmounted by the first resin layer 20, as well as the insolation of the first resin layer 20 by the first radiation R₁ through the first mask 100.

The passage from FIG. 5A to FIG. 5B illustrates the development of the first resin layer 20. As in the other embodiments, a plurality of first structures 25 formed in the first resin layer 20 are thus obtained. There again, as illustrated, the height h₂₅₁, h₂₅₂, h₂₅₃, h₂₅₄ of each first structure 25 is in the first range Δ₁. As illustrated, the heights h₂₅₁, h₂₅₂, h₂₅₃, h₂₅₄ of the first structures 25 are not all identical. As indicated above, at least two are different from one another. In the example illustrated, the first structures 25 all have different heights.

In this embodiment, the first mask 100 comprises a continuous opaque zone 130. The opaque zone 23 preferably extends above a major part of the first resin layer 20, for example, above at least half of the surface of the first resin layer 20. This opaque zone 130 makes it possible to locally preserve the entire height of the first resin layer 20. After development of the first resin layer 20, a residual layer 23 is thus obtained, having a thickness e₂₅₃ equal to e₂₀. As above, it is possible to configure the first mask 100, such that the residual layer 23 has a thickness e₂₅₃ of between 0 (excluded, or thus the zero thickness is taken locally) and e₂₀. Moreover, the residual layer 23 can have a non-homogeneous thickness.

As in the other embodiments, the first mask 100 moreover comprises zones 120, neither fully transparent, nor fully opaque, called intermediate zones 120, dedicated to the formation of the first structures 25 with distinct heights, according to the principle of grayscale lithography.

Preferably, the first mask 100 used in this embodiment comprises transparent zones 110. These transparent zones 110 make it possible to locally remove the first resin layer 20 over its entire height. The upper face 11 of the substrate 10 is thus preferably locally exposed between the first structures 25 (see FIG. 5B).

Advantageously, at this stage of the method, a hardening of the first resin layer 20, i.e. a hardening of the first structures 25 and of the residual layer 23 is proceeded with.

FIG. 5C illustrates the deposition of the second photosensitive resin layer 30 on the substrate 10. As illustrated, the second resin layer 30 extends over the first structures 25 and over the residual layer 23. It moreover extends directly in contact with the upper face 11 of the substrate 10 in the zones, where this has been updated by insolation and development of the first resin layer 20.

FIG. 5D illustrates the insolation of the second resin layer 30 by the second radiation R₂ through the second mask 200. In the present embodiment, the second mask 200 corresponds to the first mask 100 having undergone a translation relative to the substrate 10. To do this, it is possible to move the first mask 100, the substrate 10, or both.

The passage from FIG. 5D to FIG. 5E illustrates the development of the second resin layer 30. Thus, a plurality of second structures 35 is obtained, each formed by a portion of the second resin layer 30 and a portion of the residual layer 23.

As illustrated, the height h₃₅₁, h₃₅₂, h₃₅₃, h₃₅₄ of each second structure 35 is in the second range Δ₂. Due to the use of the same mask 100 for the two steps of exposure to the insolation radiation, the height h₃₅₁, h₃₅₂, h₃₅₃, h₃₅₄ of each second structure 35 is equal to the sum of the local thickness e₂₅₃ of the residual layer 23 and of the height h₂₅₁, h₂₅₂, h₂₅₃, h₂₅₄ of the first structure 25 formed by the same zone in the mask 100: h₃₅₁=e₂₃+h₂₅₁, h₃₅₂=e₂₃+h₂₅₂, h₃₅₂=e₂₃+h₂₅₂, h₃₅₂=e₂₃+h₂₅₂.

As illustrated, the heights h₃₅₁, h₃₅₂, h₃₅₃ of the second structures 35 are not all identical. As indicated above, at least two are different from one another. In the example illustrated, the second structures 35 all have different heights.

In the case typically where the residual layer 23 has a uniform thickness (constant e₂₃), this embodiment thus makes it possible to form assemblies of structures 25, 35 having the same height differences to one another. By means of a suitable sizing of e₂₃, it is possible that the structures 25, 35 all gradually have one same height difference.

As in the other embodiments, advantageously, the insolation and the development of the second resin layer enables the updating of the first structures 25. In this embodiment, as illustrated in FIG. 5D, the simple movement of the mask 100 relative to the substrate 10 can be sufficient to directly expose the first structures 25 and the portion of the second resin layer 30 covering them to the second radiation R₂. It is therefore not necessary to provide in the mask 100, transparent zones dedicated to the direct insolation of the region of the first structures 25.

Thus, in this embodiment, one single mask 100 enables the formation of the first structures 25 in the first range of heights Δ₁ and of the second structures 35 in the second range of heights Δ₂.

It is understood that the three embodiments described above have been described for a positive photosensitive resin. The invention however also applies to negative resins. The principles of the two main embodiments (second structures manufactured, without or with residual layer of the first resin layer) can be implemented, by using opaque zones instead of transparent zones on the first mask 100 and on the second mask 200, and conversely.

It is moreover understood that the method can be continued with the deposition of one or more other photosensitive resin layers and the formation of other structures, on the same principles as those described for two assemblies of structures 25, 35. FIG. 5F illustrates, in particular, the result being able to be obtained after having deposited a third resin layer and having exposed it through the first mask 100 having undergone another translation relative to the substrate 10. These steps have enabled the formation of third structures 45, the height of each of which is comprised in a third range of heights Δ₃. This third range of heights Δ₃ is disjoint both from Δ₁ and from Δ₂. Again, the third formed structures 45 do not all have the same height. In the example illustrated, the third structures 45 all have different heights.

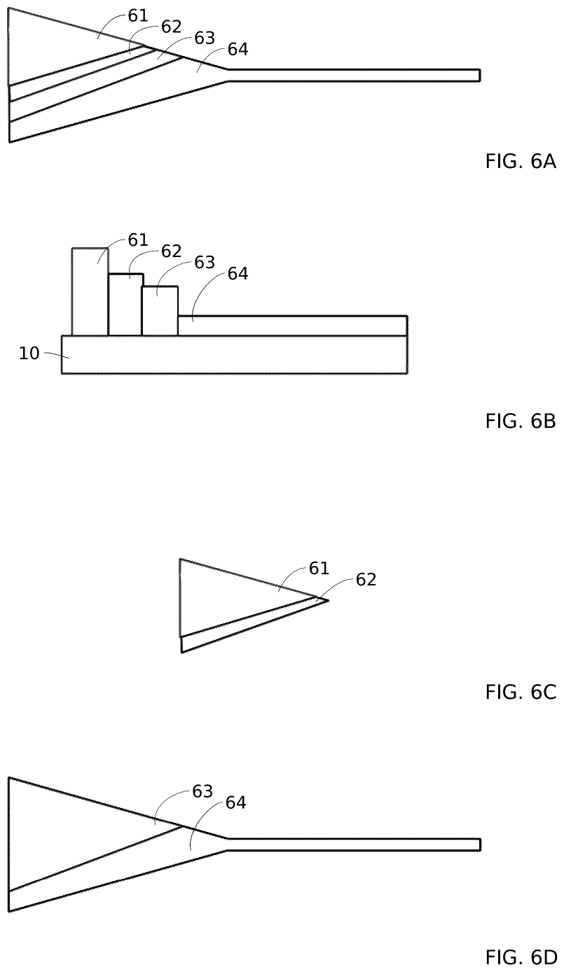

FIGS. 6A to 6D illustrate the option of using the present invention for the manufacture of various devices, in this case, a photonic coupler.

As illustrated in FIGS. 6A (top view) and 6B (cross-sectional view), a photonic coupler is formed of several structures 61, 62, 63, 64 with the basis of a dielectric material. The method according to the invention can be used to manufacture a mould which will serve for the manufacture of such a coupler. It is, in particular possible to initially form resin structures, corresponding to a part of the structures of the coupler (for example, the structures 61 and 62, see FIG. 6C), then of the resin structures corresponding to the rest of these structures (for example, the structures 63 and 64, see FIG. 6C).

Regarding the different embodiments described above, it appears that the present invention provides an effective solution for improving the accuracy on the height of the structures formed by photolithography.

The invention is not limited to the embodiments described above, and extends to all the embodiments covered by the invention.

1. A grayscale lithography method comprising:
providing a substrate having an upper face extending mainly into a horizontal plane, the substrate being covered by a first photosensitive resin layer,
exposing the first photosensitive resin layer to a first insolation radiation (R₁) through a first mask, then developing the first photosensitive resin layer, the first mask being configured, such that once the first resin layer is developed, an assembly of first structures is formed, each first structure having a height comprised in a first range of heights (Δ₁), the height of the first structures being measured along a direction called vertical, perpendicular to the horizontal plane,
forming on the upper face of the substrate a second photosensitive resin layer,
exposing the second photosensitive resin layer to a second insolation radiation (R₂) through a second mask, and developing the second photosensitive resin layer, the first mask and the second mask being configured, such that the developing of the second resin layer enables forming an assembly of second structures, each second structure having a height comprised in a second range of heights (Δ₂) disjoint from the first range of heights (Δ₁), the height of the second structures being measured along the vertical direction, the first structures and the second structures being located in distinct zones, projecting into the horizontal plane, the first mask and the second mask moreover being configured, such that within the assembly of first structures, at least two first structures have distinct heights, and such that within the assembly of second structures, at least two second structures have distinct heights.

2. The method according to claim 1, wherein the first mask and the second mask are configured, such that the first range of heights (Δ₁) and the second range of heights (Δ₂) each extend over a range less than or equal to 300 nm.

3. The method according to claim 1, wherein the first mask and the second mask are configured, such that the heights of the first structures are less than the heights of the second structures.

4. The method according to claim 1, further comprising, after the exposing and the developing of the first photosensitive resin layer and before the forming of the second photosensitive resin layer, a hardening of the first photosensitive resin layer.

5. The method according to claim 1, wherein the first mask has zones which are transparent to the first insolation radiation (R₁), such that the developing of the first resin layer causes, outside of the first structures, a removal of the first resin layer over an entire height along the vertical direction.

6. The method according to claim 1, wherein the first mask is configured, such that once the first resin layer is developed, outside of the first structures, a residual layer is formed, and wherein each of the second structures comprises a part of the residual layer.

7. The method according to claim 6, wherein the first mask has zones which are opaque to the first insolation radiation (R₁), such that the residual layer has at least locally, a height equal to a height of the first resin layer before insolation and development, the height of the residual layer and the height of the first resin layer being measured along the vertical direction.

8. The method according to claim 6, wherein the second mask is the first mask having undergone a translation relative to the substrate.

9. The method according to claim 1, wherein the second photosensitive layer is deposited on the first structures, and wherein the second mask has zones which are transparent to the second insolation radiation (R₂), such that the developing of the second resin layer causes updating of the first structures.

10. The method according to claim 1, wherein the at least two first structures having distinct heights have a height difference, called first height difference, greater than or equal to 20 nm.

11. The method according to claim 1, wherein the at least two second structures having distinct heights have a height difference, called second height difference, greater than or equal to 20 nm.

12. A method of manufacturing a photonic device, said method comprising the steps of the method according to claim 1, wherein the photonic device is among: a multispectral filter, a phase array, an imager, a coupler.
